(19) United States
(12) Patent Application Publication
(10) Pub. No.: US 2007/0026145 A1
(43) Pub. Date: Feb. 1, 2007

(54) Method and device for the production of a three-dimensional moulded body

(76) Inventors: Markus Lindemann, Gerlingen (DE); Bernd Hermann Renz, Marbach (DE); Joachim Hutfless, Ditzingen-Schockingen (DE)

Correspondence Address: KRIEGSMAN & KRIEGSMAN, 30 TURNPIKE ROAD, SUITE 9, SOUTHBOROUGH, MA, 01772, US

(21) Appl. No.: 10/572,138

(22) PCT Filed: Sep. 10, 2004
(86) PCT No.: PCT/EP04/10147

§ 371 Date: Mar. 15, 2006

(30) Foreign Application Priority Data
Sep. 15, 2003 (DE) 103 42 883.6

(51) Int. Cl. B29C 35/08; C23C 16/00

(52) U.S. Cl. 427/248.1

(57) ABSTRACT

The invention relates to a method for the production of a three-dimensional moulded body (52) by successively solidifying layers of a powdery construction material (57), which can be solidified by means of electromagnetic radiation or partial radiation, on points corresponding to the respective cross section of the moulded body (52). A carrier (43), which receives the moulded body (52) after the moulded body (52) is produced in a construction chamber (42), is displaced from a working position into a cooling position (121), wherein at least the carrier (43) is cooled or is driven into a suction position (128), wherein the non-solidified construction material (57) is removed from the construction chamber (42) or is moved into a cooling and suction position, wherein the non-solidified construction material (57) is removed from the building chamber (42) and the carrier (43) is cooled.

The invention relates to a process and a device for the production of a three-dimensional molded body in accordance with the preamble of claim 1 and claim 16, respectively.

The present invention deals with generative manufacturing processes in which complex, three-dimensional components are built up in layers from material powders. The application areas for the invention include, in addition to rapid prototyping and the related disciplines of rapid tooling and rapid manufacturing, in particular the production of series tools and functional parts. These include, for example, injection molds with cooling passages close to the surface and also individual parts and small series of complex functional components for medical technology, mechanical engineering, aircraft and automotive construction.

The generative manufacturing processes which are of relevance to the present invention include laser melting, which is known, for example, from DE 196 49 865 C1, in the name of Fraunhofer-Gesellschaft, and laser sintering, which is known, for example, from U.S. Pat. No. 4,863,538, in the name of the University of Texas.

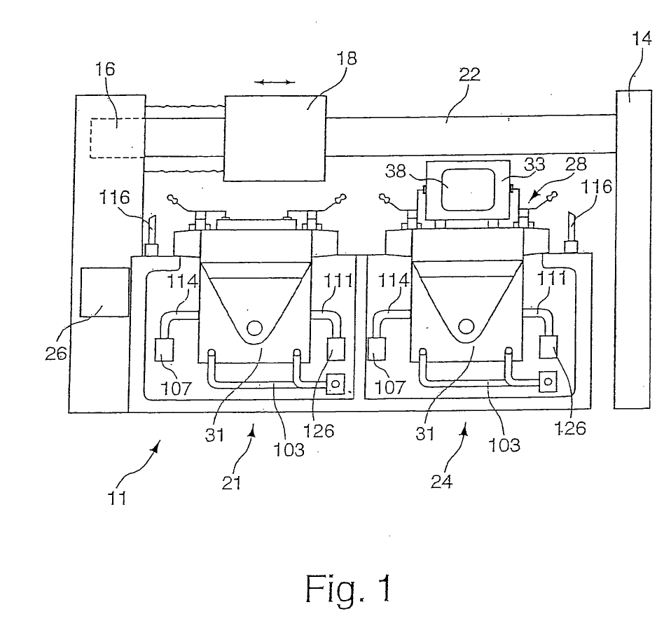

In the laser-melting process which is known from DE 196 49 865 C1, the components are produced from commercially available, single-component metallic material powders without binders or other additional components. For this purpose, the material powder is in each case applied as a thin layer to a building platform. This powder layer is locally fused using a laser beam in accordance with the desired component geometry. The energy of the laser beam is selected in such a way that the metallic material powder is completely fused over its entire layer thickness at the location of incidence of the laser beam. At the same time, a shielding gas atmosphere is maintained above the zone where the laser beam interacts with the metallic material powder, in order to avoid defects in the component which may be caused, for example, by oxidation. It is known to use a device shown in FIG. 1 of DE 196 49 865 C1 to carry out the process.

In the laser-sintering process which is known from U.S. Pat. No. 4,863,538, the components are produced from material powders which have been specially developed for laser sintering and which, in addition to the base material, contain one or more additional components. The different powder components differ in particular in terms of the melting point. In the case of laser sintering, the material powder is applied to a building platform as a thin layer. This powder layer is locally irradiated with a laser beam in accordance with the geometry data of the component. The low-melting components of the material powder are fused by the laser energy which is introduced, while others remain in the solid state. The layer is secured to the previous layer by means of the fused powder components, which produce a bond on solidification. After a layer has been built up, the building platform is lowered by the thickness of one layer, and a new powder layer is applied from a storage vessel.

After the three-dimensional molded body is produced, the build-up material which has not been consolidated is removed from the build-up chamber by the machine operator by means of an external suction apparatus. For this purpose, the building platform, which is arranged moveably in the build-up chamber, is moved upward in order to use the suction apparatus to remove the build-up material which has not been consolidated.

This procedure has the disadvantage that, because of the use of personnel, production of a molded body is cost-intensive. In addition, the manual sucking-out operation stands in the way of automating the process.

DE 199 37 260 A1 reveals a process, in which a controlled removal of build-up material which has not been consolidated takes place in a separate device outside the process chamber for producing a molded body. A vessel is provided for this, which vessel can be used both in the process chamber for producing the molded body and in the separate device for removing the build-up material which has not been consolidated.

The molded bodies are generally produced at high temperatures of up to 500° C. in order to obtain a good connection between the individual layers and to allow the molded body to be built up with low stresses and without cracks. In order to handle the vessel after the molded body is produced, a defined cooling phase has to be provided in order to allow safe handling of the vessel. In addition, the finished molded body should be cooled uniformly and at a suitable speed in order to reduce stresses in the molded body.

Therefore, the invention is based on the object of providing a process and a device for the production of a three-dimensional molded body, in which process and in which device the production time of the molded body is shortened and the handling is simplified.

This object is achieved by a process as claimed in patent claim 1 and by a device as claimed in patent claim 16. Expedient developments and refinements of the invention are described in the respective dependent claims.

After the molded body is finished in a process chamber, a carrier receiving the molded body is moved within a build-up chamber from a machining position into a cooling position, suction position or cooling and suction position. The positions within the build-up chamber are moved to as a function of the machining strategy, the duration of the process, the build-up material, the geometry of the molded body, and also further process parameters for the production of a molded body. The positioning of the carrier within the build-up chamber enables the build-up material which partially surrounds the molded body and has not been consolidated to be temporarily stored within the build-up chamber during cooling until the extraction operation, and, in a suction position, to be completely discharged within a short time.

According to an advantageous refinement of the invention, it is provided that, before or after the direct or indirect cooling of the molded body, the carrier is moved into a suction position, in which the build-up material which has not been consolidated is removed from the build-up chamber. For this, a volumetric flow is produced which passes through the build-up chamber, as a result of which a removal of the build-up material which has not been consolidated and a cooling of the molded body and of the carrier takes place.

In a preferred embodiment, first of all a direct cooling of the carrier and an indirect cooling of the molded body take place. During this cooling-down phase, the build-up chamber can also be cooled. Subsequently, the build-up material which has likewise been at least partially cooled down and has not been consolidated is removed from the build-up chamber.

In order to remove build-up material which has not been consolidated and in order to cool the carrier and the finished molded body, it is advantageously provided that a suction stream passes through the build-up chamber. The pulverulent build-up material which has not been consolidated can be removed in a simple manner in the suction position of the carrier. This makes it possible to provide both a high degree of efficiency for the production of molded bodies and a considerable reduction in the pollution of the environment due to build-up material which has not been consolidated. A simple and effective cooling of the carrier can be provided by a volumetric flow passing through the carrier. Thus, with different positioning of the carrier within the build-up chamber, a plurality of functions can be carried out with a volumetric flow.

During the building up of the molded body, the building platform is heated to a temperature of, for example, 300° C. to 500° C. by heating elements. In order to cool the carrier after the molded body is finished, it is advantageously provided that the carrier is transferred into a cooling position, in which the building platform of the carrier is passed through at least partially by the flow and is cooled. By the building platform being passed through at least partially by the flow, first of all a rapid cooling of the building platform can take place and at the same time an indirect cooling of the molded body which rests on the building platform can be brought about.

The at least one inlet opening in the build-up chamber for feeding in the volumetric flow is provided essentially congruently to cooling passages of the building platform in a cooling position. As a result, a good throughflow with a high throughflow speed can be provided, thus resulting in efficient cooling.

The production of the cooling stream preferably takes place by ambient air being sucked in. This is preferably filtered before being fed into the build-up chamber. As a result, purified air can be fed in. In addition, this refinement is cost-effective, since the purified air of the cooling stream can be discharged again into the environment. At the same time, this refinement has the advantage that with one and the same feeding in of the ambient air and with the inlet and outlet openings provided in the build-up chamber, both the sucking out of the build-up material which has not been consolidated and the cooling of the building platform and of the molded body are made possible.

As an alternative to the configuration of a suction stream, provision may be made for the ambient air or a gaseous medium to be fed in under pressure by a fan connected upstream of the at least one inlet opening. Furthermore, provision may alternatively be made for a gas stream or gas/air stream to be used for cooling the building platform and the molded body.

According to a further advantageous refinement of the invention, it is provided that a pulsed volumetric flow is produced for cooling the building platform. As a result, the speed at which the building platform and the molded body are cooled down can be influenced as a function of the pulse duration and/or of the volumetric flow. The molded body is preferably cooled down uniformly within a period of time matched to the shape, size and/or the build-up material of the molded body in order to avoid the building up of internal stresses.

In order to simultaneously cool the building platform and the molded body, according to an advantageous development of the invention, it can be provided that the carrier can be brought into a position, so that inlet and outlet openings are provided in the build-up chamber level with the cooling passages of the carrier and, furthermore, inlet and outlet openings are arranged in the region of the molded body or inlet and outlet openings covering both regions are provided. As a result, a simultaneous cooling of molded body and building platform and the removal of build-up material which has not been consolidated can be made possible.

In order to make it possible, for example, to separately cool building platform and molded body, the volumetric flows for cooling the building platform and the molded body are preferably set and actuated separately in each case. As a result, the cooling-down rate of the building platform can be substantially higher than that of the molded body. At the same time, by means of the separate volumetric flow which is provided for the molded body, a further cooling of the build-up chamber can be made possible.

In order to remove build-up material which has not been consolidated, in particular by means of the production of a suction stream, the building platform is positioned below or from below adjacent to at least one outlet opening in the build-up chamber. This also makes it possible to suck out a base surface of a building platform on which the molded body is built up and which is not occupied by the molded body.

The beginning of the extraction is preferably monitored by a sensor element which, after a closure element is fitted onto an opening of the build-up chamber, passes on a signal to a control and arithmetic unit. This ensures that a closed build-up chamber is provided for removing the build-up material which has not been consolidated. During the removal by means of a suction stream of the build-up material which has not been consolidated, swirls are produced in the closed space. This makes it possible for at least some of the powder particles which are adhering to the molded body and have not been consolidated to be detached and sucked out.

As an alternative, it can be provided that the production of the suction stream is actuated manually after it has been confirmed by way of the control system that a closure element has been provided on the opening of the build-up chamber.

According to an advantageous refinement of the process, it is provided that the carrier is moved at least slightly up and down during the removal of the build-up material which has not been consolidated. This makes it possible, by a volumetric flow entering the build-up chamber, for a relatively large region of the molded body to be subjected to the incident flow. As a result, the detaching of build-up material which is adhering to the molded body but which has not been consolidated can be increased. The up and down movement can be controlled by a control and arithmetic unit, with the movement distance and the movement duration being set in a manner specific to the application.

According to a further advantageous embodiment of the process, it is provided that in order to cool or suck out build-up material which has not been consolidated a continuous volumetric flow, an increasing, pulsating or decreasing volumetric flow is produced. The volumetric flows are set as a function of the geometry of the molded body, the type of build-up material and the operating temperature. For example, with an increasing volumetric flow, first of all a substantial portion of build-up material which has not been consolidated can be sucked out in order, toward the end of the sucking-out operation, to obtain a high degree of swirling with a small amount of build-up material still remaining and therefore to increase the cleaning effect.

If the build-up material which has not been consolidated is not removed completely, for example from cavities and undercuts of the molded body, a suction nozzle to be actuated manually is advantageously used for the cleaning. For this, the molded body remains at least partially in the build-up chamber, so that controlled cleaning can take place.

In order to produce a suction stream, use is preferably made of a fan which produces a plurality of suction streams for at least two process chambers. This fan is preferably designed as a radial fan. The efficiency of the fan makes it possible for a plurality of process chambers to be operated. The volumetric flow for producing a suction power is determined both by the cross section of the inlet and outlet openings and by a setting of the suction parameters on the fan.

The sucking out of the build-up material which has not been consolidated is preferably carried out with an air stream. In order to suck out very warm build-up material which has not been consolidated, a gas/air stream or a gas stream is preferably provided in order to avoid sparking and therefore to reduce a risk of explosion.

The build-up material which has not been consolidated and is discharged by a suction stream is advantageously fed to a separation device and a filter. These components are connected downstream of the barrier devices, which serve to control the process, in the sucking-out lines. As a result, a cleaning and filtration of the volumetric flow, in particular of the air stream or gas stream, can be obtained, so that it can be discharged again to the environment. At the same time, a recycling of the build-up material which has not been consolidated for renewed use in the layered build-up can be made possible. The recycled build-up material which has not been consolidated is advantageously sieved and cleaned. This can take place in a cleaning and preparation unit integrated in the separation device or an external unit.

According to an advantageous embodiment of the invention, the cooling of the building platform and therefore of the molded body is monitored by means of a temperature sensor arranged in the building platform. As a result, a controlled cooling can take place and the pulse duration and/or the volumetric flow can advantageously be set and adapted in manner and throughflow rate by the control and arithmetic unit as a function of the temperature actually recorded.

The cooling position is assumed until preferably a temperature on or in the building platform of the carrier of less than 50° C. is recorded by the temperature sensor. When the temperature drops below this temperature, a signal is output, and the carrier moves into a further position, in which the build-up material which has not been consolidated is sucked out of the build-up chamber, and subsequently into a position, in which the molded body is removed by the building platform out of the build-up chamber.

Like the suction stream for sucking out the build-up material which has not been consolidated, the volumetric flow for cooling at least the building platform is advantageously supplied to a separation device and a filter which are connected upstream of a fan. As a result, a reduction of the component parts and simplification of the build-up can be provided.

In order to carry out the process according to the invention, in particular a device in accordance with the preamble of claim 16 is provided, which device has at least one inlet opening and at least one outlet opening for a volumetric flow of a medium which passes through the build-up chamber in at least one wall section of the build-up chamber.

As a result, a removal of build-up material which has not been consolidated and/or a cooling of the carrier or the components thereof can be provided as a function of the position of the carrier within the build-up chamber with respect to the at least one inlet opening and at least one outlet opening. At the same time, a sucking out or removal of build-up material which has not been consolidated, which sucking out or removal is integrated in a process chamber, and cooling at least of the carrier and, if appropriate, of the build-up chamber can be provided. The integrated arrangement and configuration for cooling the component parts and for removing build-up material which has not been consolidated result in a reduction in the process duration and therefore in an increase in economy. Also, the risk of polluting the environment and associated health risks due to build-up material which has not been consolidated when the molded body is removed from the build-up chamber are considerably reduced.

According to an advantageous refinement of the device, it is provided that the at least one inlet opening or at least one outlet opening or the at least one inlet and the at least one outlet opening of the process chamber is/are in each case assigned a barrier device. As a result, the process chamber can be locked hermetically when the need arises. It is possible, for example, for one suction fan to be provided for a plurality of process chambers in order to produce an intake stream or volumetric flow. By closing the inlet and/or outlet openings, the process chambers are independent of one another with regard to sucking out and cooling, thus allowing an efficient manner of operation and full utilization of a beam source.

According to a further advantageous refinement of the device, it is provided that a respective barrier device is provided in an outlet opening of a build-up chamber, in an outlet opening of a powder trap of the process chamber and preferably in a discharge line of a nozzle for manual extraction. All of the openings which are arranged between the process chamber or build-up chamber and the fan can therefore be closed. The barrier devices are preferably actuable individually or in groups, so that the barrier devices are opened or closed in accordance with the current working steps and process parameters. This can furthermore result in an infinitely variable setting of the volumetric flow for cooling and/or sucking out being possible. Thus, in addition to changing the volumetric flow via the fan power, a setting of the volumetric flow which passes through the process chamber can also be made possible via the barrier devices. The barrier devices are preferably designed as pinch valves which have a long service life.

In order to remove build-up material which has not been consolidated, a volumetric flow of gas, ambient air or a gas/air mixture is preferably provided. The selection of the medium for the volumetric flow for sucking out build-up material which has not been consolidated is dependent on the material powder used. Sucking out with ambient air is preferably provided. In order to suck out build-up material which has not been consolidated even at higher temperatures and to prevent a possible risk of explosion, the sucking out is alternatively provided under shielding gas.

At least one inlet opening and outlet opening are arranged opposite each other in the build-up chamber for the flow through the build-up chamber. As a result, a high degree of efficiency for removing the build-up material which has not been consolidated and for cooling the carrier and/or the process chamber can be obtained.

According to a further advantageous refinement of the invention, it is provided that at least one inlet opening is arranged in the wall section of the build-up chamber at the same height as the at least one outlet opening or higher. For example, when build-up material which has not been consolidated is removed, a stepped configuration of at least one inlet opening and at least one outlet opening may be advantageous, as a result of which a specific swirling of the remaining build-up material which has not been consolidated is produced within the build-up chamber.

The number of inlet openings and of outlet openings is preferably identical. A uniform and constant throughflow can be obtained as a result. As an alternative, it can be provided that the number of inlet openings is designed to be lower than the number of outlet openings, preferably while being identical in size, in order to obtain a nozzle effect in the build-up chamber for removing the build-up material which has not been consolidated and for cooling. In a departure from this, a corresponding numerical ratio can be selected by changing the size of the inlet openings with respect to the outlet openings.

For the uniform flow through the build-up chamber, it is furthermore advantageously provided that the geometries of the at least one inlet opening and at least one outlet opening are of similar or identical design. It can advantageously be provided that at least the inlet openings are of nozzle-shaped design in order, for example, to obtain an increased inflow speed, as a result of which build-up material which has not been consolidated can more easily be detached from the molded body.

According to a further advantageous refinement of the invention, it is provided that a plurality of inlet openings are provided within a segment region on the peripheral wall of the build-up chamber. As a result, for example, a region of up to 180° can be provided within which inlet openings are positioned. By means of the in particular nozzle-shaped configuration, a targeted blasting of the molded body can be obtained. In particular with an additional up and down movement of the carrier, at least a pre-cleaning of the molded body can be provided. The inlet and outlet openings may also be provided in groups or may be matched to the shape and arrangement of the cooling passages of the carrier.

According to a further advantageous refinement of the invention, it is provided that the at least one building platform of the carrier has cooling passages which are arranged essentially congruently to the at least one inlet and outlet openings in a cooling position of the process chamber. As a result, a high throughflow speed can be obtained, thus making increased transportation of heat possible. According to a preferred embodiment, the geometry of the at least one inlet opening and at least one outlet opening corresponds to the geometry of the cooling passages which are provided in particular in the building platform. This allows an interference-free coupling of the volumetric flow and optimum cooling to be obtained.

The at least one inlet opening and at least one outlet opening are advantageously provided at a distance below a base surface in the build-up chamber corresponding at least to the maximum overall height of a molded body to be produced. This enables the carrier to be lowered in the build-up chamber after the molded body is produced and a specific discharge of build-up material which has not been consolidated is made possible.

According to a further advantageous refinement of the invention, it is provided that the throughflow rate of the volumetric flow for removing build-up material which has not been consolidated and preferably also for cooling the carrier is controlled by a fan. As an alternative, it can be provided that the throughflow rate of the volumetric flow is controlled by limiting an opening cross section of the inlet and outlet opening.

The process chamber advantageously comprises a filter through which purified ambient air or an alternative cooling medium is fed to a build-up chamber via a feed line.

Like the suction stream for sucking out the build-up material which has not been consolidated, the volumetric flow for cooling the building platform and the molded body is advantageously fed to a separation device and preferably to a filter.

According to a further advantageous refinement of the invention, it is provided that the finished molded body is positioned rotatably on the carrier. The rotatable arrangement of the molded body increases the cleaning effect when removing the build-up material which has not been consolidated.

The molded body is preferably rotated at least once through 360°, so that each peripheral section of the molded body is assigned to the at least one inlet opening. At the same time, the rotation and swirling caused in the build-up chamber can cause additional pulses on the surface of the molded body in order to increase the cleaning effect. In addition, the rotatable arrangement of the molded body during the removal of build-up material which has not been consolidated and the simultaneous cooling of the build-up chamber has the advantage that a uniform cooling on the surface is made possible by the volumetric flow flowing in or through.

The invention and further advantageous embodiments and developments thereof are described and explained in more detail below with reference to the examples illustrated in the drawings. According to the invention, the features revealed in the description and the drawings can be employed individually on their own or in any desired combination. In the drawings:

FIG. 1 shows a diagrammatic side view of a device according to the invention,

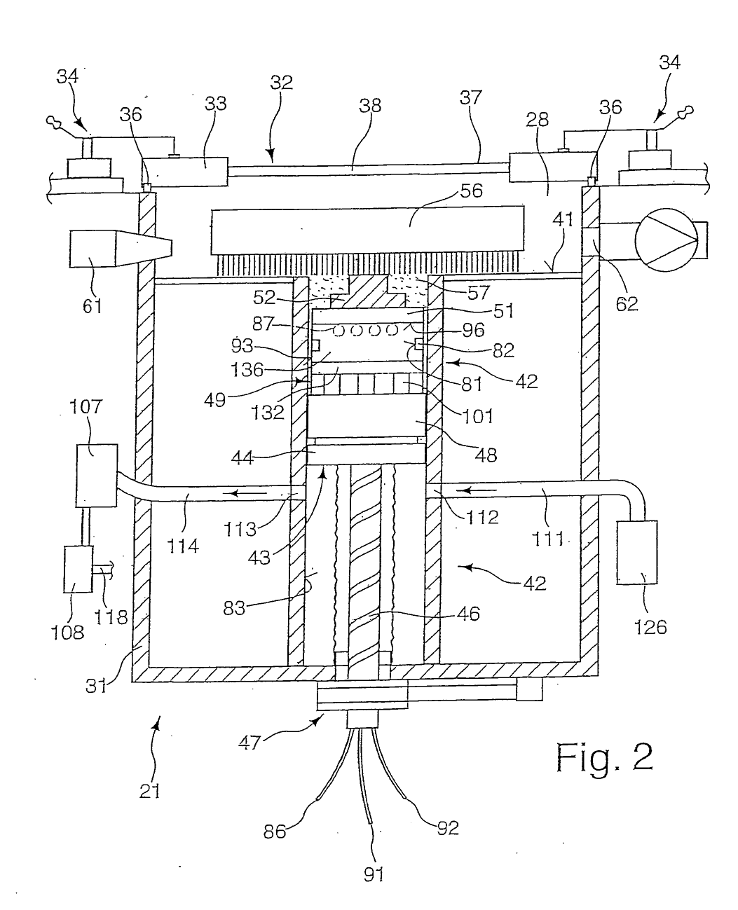

FIG. 2 shows a diagrammatic sectional illustration of a process chamber in a machining position during production of a molded body,

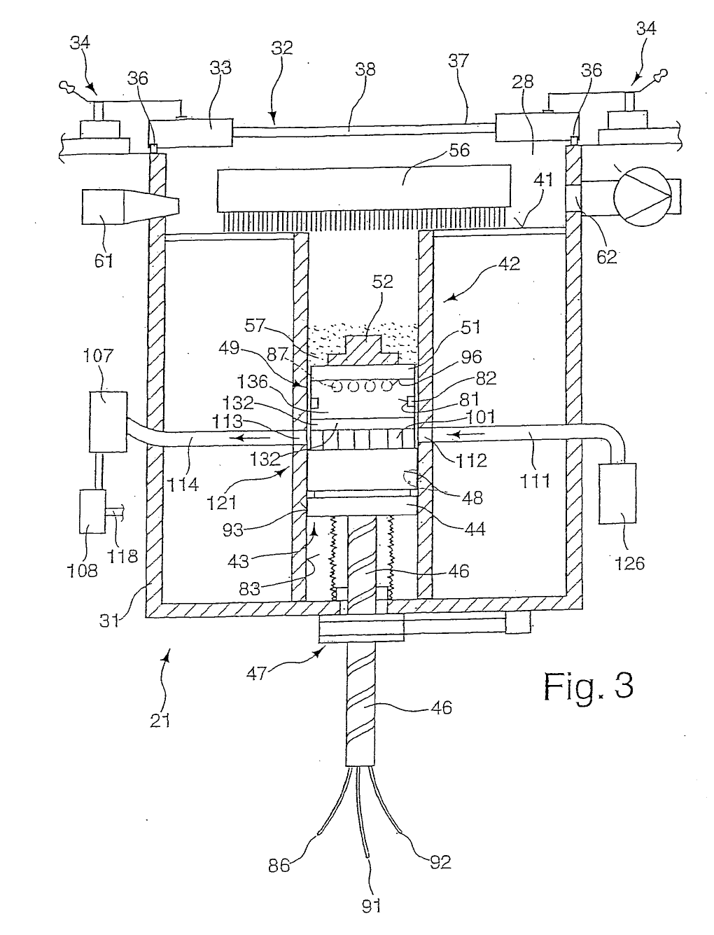

FIG. 3 shows a diagrammatic sectional illustration of the process chamber shown in FIG. 2 after layered build-up of a molded body, in a cooling position,

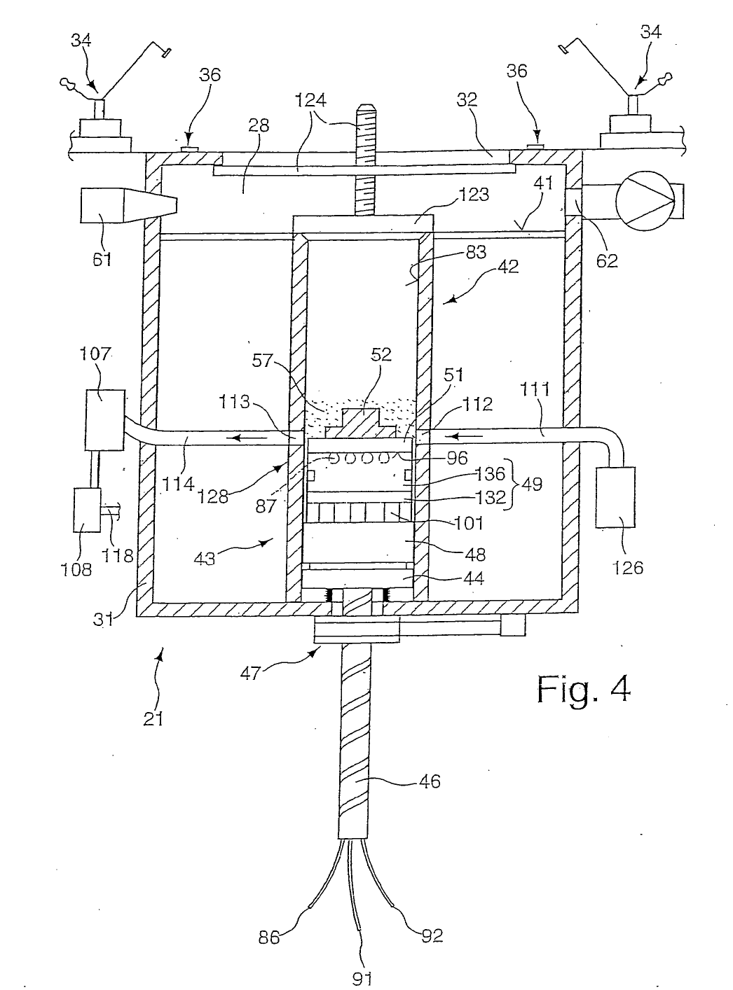

FIG. 4 shows a diagrammatic sectional illustration of the process chamber shown in FIG. 2 after layered build-up of a molded body, in a suction position,

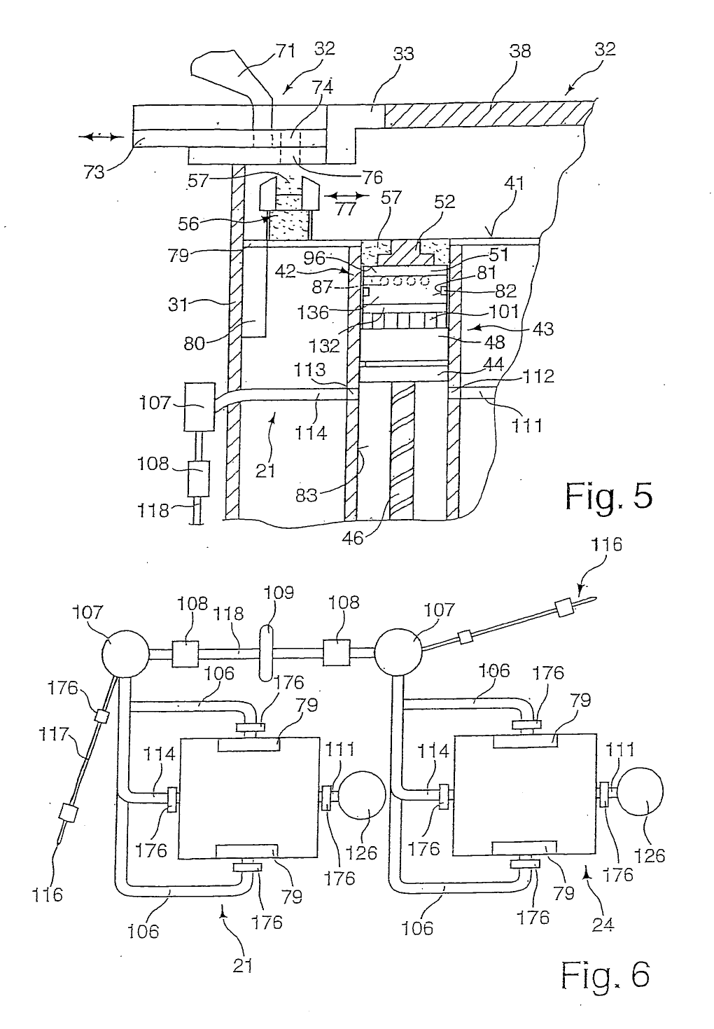

FIG. 5 shows a diagrammatic part-section through a process chamber with a feed device,

FIG. 6 shows a diagrammatic illustration of two process chambers and a connection between the associated components, and

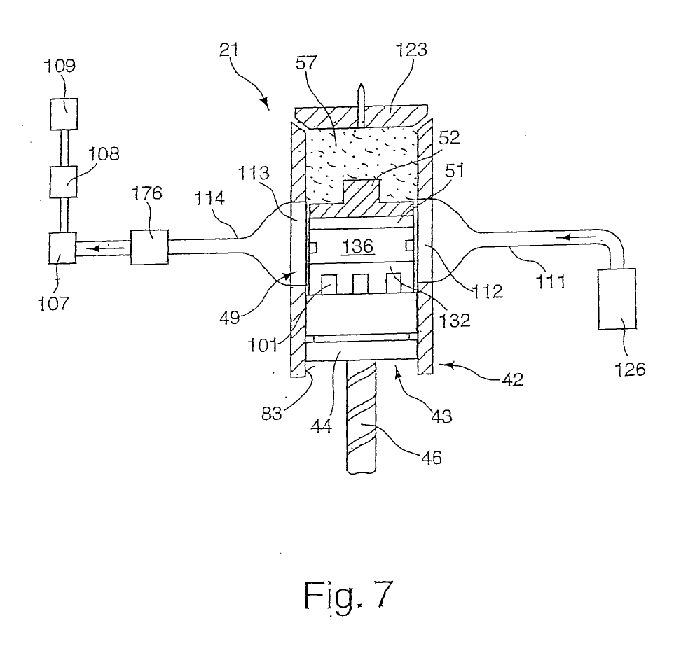

FIG. 7 shows a diagrammatic view of a build-up chamber with an alternative feeding in of volumetric flows.

FIG. 1 diagrammatically depicts a device 11 according to the invention for the production of a three-dimensional molded body by successive consolidation of layers of a pulverulent build-up material. The production of a molded body by laser fusion is described, for example, in DE 196 49 865 C1. The device 11 comprises a beam source 16, which is arranged in a machine frame 14, in the form of a laser, for example a solid-state laser, which emits a directed beam. This beam is focused via a beam-diverter device 18, for example in the form of one or more actuable mirrors, as a diverted beam onto a working plane in a process chamber 21. The beam-diverter device 18 is arranged such that it can be displaced by motor means along a linear guide 22 between a first process chamber 21 and a further process chamber 24. The beam-diverter device 18 can be moved into a precise position with respect to the process chambers 21, 24 by means of actuating drives. Furthermore, the machine frame 14 provides a control and arithmetic unit 26 for operation of the device 11 and for setting individual parameters for the working processes used to produce the molded bodies.

The first process chamber 21 and at least one further process chamber 24 are arranged separately from one another and are hermetically isolated from one another.

FIG. 2 illustrates the process chamber 21, by way of example, fully in cross section. The process chamber 21 comprises a housing 31 and is accessible through an opening 32 which can be closed off by at least one closure element 33. The closure element 33 is preferably designed as a pivotable cover which can be fixed in a closed position by locking elements 34, such as for example toggle lever elements. A seal 36, which is preferably formed as an elastomer seal, is provided at the housing 31, close to the opening 32, to seal off the process chamber 21. The closure element 33 has a region 37 which transmits the electromagnetic radiation of the laser beam. It is preferable to use a window 38 made from glass or quartz glass which has anti-reflection coatings on the top side and the underside. The closure element 33 may preferably be of water-cooled design.

The process chamber 21 comprises a base surface 41. A build-up chamber 42, in which a carrier 43 is provided and guided such that it can move up and down, opens out into this base surface 41 from below. The carrier 43 comprises at least one base plate 44, which is driven such that it can be moved up and down by means of a lifting rod or lifting spindle 46. For this purpose, a drive 47, for example a toothed belt drive, is provided to move the fixed lifting spindle 46 up and down. The base plate 44 of the carrier 43 is preferably cooled by a fluid medium, which preferably flows through cooling passages in the base plate 44, at least during the layered build-up. An insulation layer 48 made from a mechanically stable, thermally insulating material is arranged between the base plate 44 and the building platform 49 of the carrier 43. This prevents the lifting spindle 46 from being heated by the heating of the building platform 49, with an associated effect on the positioning of the carrier 43.

An application and leveling device 56, which applies a build-up material 57 into the build-up chamber 42, moves along the base surface 41 of the process chamber 21. A layer is built up on the molded body 52 by selective fusion of the build-up material 57.

The build-up material 57 preferably comprises metal or ceramic powder. Other materials which are suitable and used for laser fusion and laser sintering are also employed. The individual material powders are selected as a function of the molded body 52 to be produced.

On one side, the process chamber 21 has an inlet nozzle 61 for the supply of shielding gas or inert gas. At an opposite side, there is an extraction nozzle or extraction opening 62 for removing the supplied shielding or inert gas. During production of the molded body 52, a laminar flow of shielding or inert gas is generated, in order to avoid oxidation during fusion of the build-up material 57 and to protect the window 38 in the closure element 33. It is preferable for the hermetically locked process chamber 21 to be held at a superatmospheric pressure of, for example, 20 hPa during the build-up process, although significantly higher pressures are also conceivable. This means that it is impossible for any atmospheric oxygen to penetrate into the process chamber 21 from the outside during the build-up process. During circulation of the shielding or inert gas, it is simultaneously also possible to realize cooling. It is preferable for cooling and filtering of the shielding or inert gas to remove entrained particles of the build-up material 57 to be provided outside the process chamber 21.

The build-up chamber 42 is preferably of cylindrical design. Further geometries may also be provided. The carrier 43 or at least parts of the carrier 43 are matched to the geometry of the build-up chamber 42. In the build-up chamber 42, the carrier 43 is moved downwards with respect to the base surface 41 in order to effect a layered build-up. The height of the build-up chamber 42 is matched to the build-up height or the maximum height to be built up for a molded body 52.

A peripheral wall 83 of the build-up chamber 42 directly adjoins the base surface 41 and extends downwards, this peripheral wall 83 being suspended from the base surface 41. At least one inlet opening 112 is provided in the peripheral wall 83. This inlet opening 112 is in communication with a feed line 111 which accommodates a filter 126 outside the housing 31. Ambient air is fed to the build-up chamber 42 through the inlet opening 112 via the filter 126 and the supply line 111. Furthermore, the build-up chamber 42 has at least one outlet opening 113 in the peripheral wall 83, to which outlet opening there is connected a discharge line 114 which leads out of the housing 31 and opens out into a separation device 107. Downstream of the latter there is a filter 108 which discharges the volumetric flow that has been discharged from the build-up chamber 42 via a connecting line 118. It is advantageously provided that the inlet opening 112 and the outlet opening 113 are aligned with one another. It is also possible for the openings 112, 113 to be arranged offset with respect to one another, both in terms of the height and in terms of their feed position in the radial direction or at right angles to the longitudinal axis of the build-up chamber 42.

The building platform 49 is composed of a heating plate 136 and a cooling plate 132. Heating elements 87 are illustrated by dashed lines in the heating plate 136. Furthermore, the heating plate 136 comprises a temperature sensor (not shown in more detail). The heating elements 87 and the temperature sensor are connected to supply lines 91, 92, which in turn are routed through the lifting spindle 46 to the building platform 49. A peripheral groove 81, in which one or more sealing rings 82 are fitted, is provided at the external periphery 93 of the building platform 49; the diameter of the sealing ring(s) 82 can be altered slightly and matched to the installation situation and temperature fluctuations. The sealing ring(s) 82 bear(s) against a peripheral wall 83 of the build-up chamber 42. This sealing ring 82 has a surface hardness which is lower than that of the peripheral wall 83. The peripheral wall 83 advantageously has a surface hardness which is greater than the hardness of the build-up material 57 provided for the molded body 52. This makes it possible to ensure that there is no damage to the peripheral wall 83 during prolonged use, and only the sealing ring 82, as a wearing part, has to be replaced at maintenance intervals. It is advantageous for the peripheral wall 83 of the build-up chamber 42 to be surface-coated, for example chromium-plated.

The base plate 44 comprises a water cooling system which is in operation at least while the molded body 52 is being built up. Cooling liquid is fed to the cooling passages provided in the base plate 44 via a cooling line 86 which is fed to the base plate 44 through the lifting spindle 46. The cooling medium provided is preferably water. The cooling allows the base plate 44 to be set, for example, to a substantially constant temperature of 20° C. to 40° C.

To receive a molded body 52, the carrier 43 has a substrate plate 51 which is positioned fixedly or releasably on the carrier 43 by means of a retaining means and/or an orientation aid. Before production of a molded body 52 commences, the heating plate 136 is heated to an operating temperature of between 300° C. and 500° C., in order to allow the molded body 52 to be built up with low stresses and without cracks. The temperature sensor (not shown in more detail) records the heating temperature or operating temperature while the molded body 52 is being built up.

The building platform 49 has cooling passages 101, which preferably extend transversely throughout the entire building platform 49. It is possible to provide one or more cooling passages 101. The position of the cooling passages 101 is, for example, illustrated adjacent to the insulating layer 48 in accordance with the exemplary embodiment. Alternatively, it is possible for the cooling passages 101 to extend not just beneath heating elements 87 but also above and/or between the heating elements 87.

After completion of the molded body 52, the carrier 43 is lowered from the machining position illustrated in FIG. 2 into a first position or cooling position 121. This position is illustrated in FIG. 3. Even while the carrier 43 is being lowered, a volumetric flow from the environment can be fed via the filter 126 and the supply line 111 to the build-up chamber 42 and discharged from the build-up chamber 42 via the outlet opening 113 and discharge line 114. The build-up chamber 42 can be cooled as early as at this stage and also while the molded body 52 is being built up.

The cooling position 121 of the carrier 43 is provided in such a manner that cooling passages 101 of the building platform 49 are aligned with the at least one inlet opening 112 and at least one outlet opening 113 in the peripheral wall 83 of the build-up chamber 42. The volumetric flow flows through the cooling passages 101, thereby cooling at least the building platform 49. The cooling may be effected by a pulsed suction stream. The cooling rate in the molded body 52 can be determined by the pulse/pause ratio. It is preferable to provide for uniform cooling for a predetermined period of time, to minimize the build-up of internal stresses in the molded body 52. The cooling may also be provided by a volumetric flow which continuously increases or decreases in quantitative terms. It is also possible to alternate between an increase and a decrease in order to obtain the desired cooling rate. The cooling rate can be recorded by the temperature sensor provided in the heating plate 136. At the same time, the residual temperature of the molded body 52 can be derived via this temperature sensor. This cooling position 121 is maintained until the molded body 52 has been cooled to a temperature of, for example, less than 50° C. At the same time, the base plate 44 can be cooled further in this cooling position 121. In addition, it is also possible to provide for cooling passages or cooling hoses to be provided adjacent to the peripheral wall 83 of the build-up chamber 42 or in the peripheral wall 83 of the build-up chamber 42, these cooling passages or cooling hoses also contributing to cooling of the build-up chamber 42, the molded body 52 and the carrier 43.

After the molded body 52 has been cooled to the desired or preset temperature, the carrier 43 is transferred into a further position or suction position 128, which is illustrated in FIG. 4. This suction position 128, which is illustrated by way of example, is used to remove, in particular suck out, the build-up material 57 which has not been consolidated during production of the molded body 52. The build-up chamber 42 is closed by a closure element 123 prior to the application of a suction stream flowing through the build-up chamber 42. This closure element 123 has securing elements 124 which act on or in the opening 32 in order to fix the closure element 123 tightly to the build-up chamber 42. The closure element 123 is preferably of transparent design, so that it is possible to monitor the sucking-out of build-up material 57 that has not been consolidated. A suction stream flowing through the build-up chamber 42 generates a swirl in the build-up chamber 42, with the result that the build-up material 57 that has not been consolidated is sucked out and fed to the separation device 107 and the filter 108. At the same time, furthermore, the suction is responsible for cooling the build-up chamber 42, the molded body 52 and the building platform 49. In addition, it is possible to effect a further supply of air via at least one nozzle in the closure element 123.

The sucking-out of the build-up material 57 can be operated by a constant volumetric flow, a pulsed volumetric flow or a volumetric flow with an increasing or decreasing mass throughput. The suction is terminated after a predetermined duration of the suction or after a period of time which can be set by the operating personnel.

To remove the molded body 52, the closure element 123 is removed from the build-up chamber 42 and the carrier 43 moves into an upper position, so that the molded body 52 is positioned at least partially above the base surface 41 of the process chamber 21 in order to be removed.

FIG. 5 illustrates an exemplary embodiment for feeding the build-up material 57 via a feed device 72 into the process chamber 21. The partial section shows a feed passage 71 which is in communication with a collection vessel or storage vessel (not shown in more detail) and provides build-up material 57. The feed device 72 comprises a slide 73, which preferably has a slot-like opening 74 which, in a first position, enables the build-up material 57 to pass into the opening 74. After the slide 73 has been positioned in a second position, the build-up material 57 stored in the opening 74 is conveyed via a gap 76 into the application and leveling device 56, which then transfers the build-up material 57 into the build-up chamber 42 as a result of a reciprocating movement indicated by arrow 77. Cutouts 79, through which excess build-up material 57 can be discharged into a receptacle or powder trap 80, are provided in the base surface 41 at the reversal points for the reciprocating movement of the application and leveling device 56. Therefore, after the build-up material 57 has been introduced into the build-up chamber 42, the base surface 41 is substantially free of build-up material 57. This configuration of the feed device 72 allows a portioned supply of build-up material 57 into the process chamber 28. Furthermore, this feed device 72 allows a rapid and simple change from one build-up material 57 to another build-up material 57, since this feed device 72 allows the build-up material 57 to be introduced into the process chamber 21 virtually without residues. Further solutions relating to the configuration of the feed device 72 are likewise possible. By way of example, the portioned supply of the build-up material 57 may also be effected by means of a controllable closure element and a sensor element by which the feed quantity is determined. It is also possible, as an alternative to the application and leveling device 56 described, to use a device which introduces the build-up material 57 into the build-up chamber 42 in the style of a printing process.

The double-chamber or multi-chamber principle is described below with reference to FIG. 6, which shows a diagrammatic plan view of the device 11 according to the invention, reference also being made at the same time to the previous figures.

Each process chamber 21, 24 comprises a filter 126, through which purified ambient air is fed to a build-up chamber 42 via a feed line 111. A discharge line 114 discharges the volumetric flow from the build-up chamber 42, and this flow, outside the housing 31, is fed to a separation device 107. A filter 108 is connected downstream of the separation device 107.

Furthermore, the process chamber 21, 24 in each case comprises a line 106 which discharges the build-up material 57 that has been collected in a powder trap 80 from the housing 31 and feeds it to the separation device 107 or the discharge line 114. This line 106 is in communication with an outlet opening of the powder trap 80 in the housing 31, through which build-up material 57 that is not required is collected.

Each process chamber 21, 24 is assigned barrier devices 176 designed as shut-off valves. In a preferred embodiment, these shut-off devices 176 are provided in the outlet opening 113 of the discharge line 114 and in the outlet openings of the powder trap 80 into which the lines for discharging powder open out. Furthermore, these barrier devices 176 may be provided between the process chamber 21, 24 in a line section of the discharge line 114 and the line 106 upstream of a separation device 107. Furthermore, it is advantageously provided that a barrier device 176 is also provided in a suction line 117 of a nozzle 116 for the manual extraction of build-up material 57 that has not been consolidated or assigned to the nozzle 116. In addition, to increase reliability, it is possible to provide further barrier devices 176. By way of example, it is possible to provide a barrier device 176 in the inlet opening 112 of the feed line 111. Furthermore, it is additionally possible to provide a barrier device 176 in the connecting lines 118 which in each case open out from the process chamber 21, 24 into the fan 109 in order to form further safety functions.

The barrier devices 176 can be actuated individually or combined in functional groups, so that the actuation is incorporated in the individual working processes, such as production of the molded body, cooling of the carrier and extraction of the build-up material 57 that has not been consolidated. This ensures that, for example during the extraction of build-up material 57 that has not been consolidated or during cooling of the carrier 43 in the process chamber 21, the process chamber 24 is hermetically locked off from the process chamber 21 by closing the barrier devices 176 of the process chamber 24. It is preferable for the barrier device 176 used to be pinch valves, which have a long service life.

The barrier devices 176 are preferably actuated as a function of the position of the carrier 43 in the build-up chamber 42. Furthermore, it is also possible for the signal for actuation of the barrier devices 176 to be coupled to the control signal for operation of the fan 109. It is preferable for all the barrier devices 176 to be closed in their at-rest position and for only the required barrier devices 176 to be opened during the suction and/or cooling in a process chamber 21, 24.

Furthermore, a suction line 117, which has a nozzle 116 for manual cleaning of the process chamber 21, 24 and the further surroundings of the process chamber 21, 24, opens out into the separation device 107.

A sensor element, which automatically switches on the fan 109 when the nozzle 116 is removed from the holder for the purpose of manual extraction by suction and opens the associated barrier device 176, so that the nozzle 116 is ready for operation, is provided at the nozzle 116 or at a frame for receiving the nozzle 116. The further barrier devices 176 remain closed.

The at least two process chambers 21, 24 furthermore preferably each have a separate cooling system 103 (FIG. 1), which cools components in and at the housing 31.

The air/gas which has been discharged from the build-up chamber 42 and the discharged build-up material 57 are therefore each fed to a separation device 107, assigned to each process chamber 21, 24, and a filter 108 connected downstream thereof. The separation device 107 comprises a collection vessel, in which the discharged build-up material 57 is collected. This collected build-up material 57 can be purified by a sieve arranged between the separation device 108 and the collection vessel or can be fed to an external preparation installation, in order subsequently to be used, via the feed device 72, for further layered build-up of a molded body 52. The separate suction which is provided for each process chamber 21, 24 makes it possible to use different build-up materials while preventing mixing or contamination of the build-up material 57. In particular, the barrier devices 176 prevent the respective circuits formed for each process chamber 21, 24 from influencing one another or becoming mixed with one another.

In order to improve the cooling and the sucking-out, in a preferred embodiment further feed lines (not illustrated specifically) are provided in the closure element 33 of the process chamber 21, 24 and through them an additional gas stream is directed from above onto the molded body 52. Barrier devices 176 which permit the gas streams to be controlled are provided between the feed lines and the process chambers 21, 24. The gases provided are in particular active gases or inert gases which avoid sparking and therefore reduce the risk of explosion. The gas which is supplied via the feed lines 111 in the carrier 43 and the additional feed lines in the closure element 33 of the process chamber 21, 24 is supplied via the sucking-out lines 106, 114 of a separation device 107, 108 and is cooled via a heat exchanger (not illustrated specifically). The cleaned and cooled gas is fed again to the process chamber 21, 24 in a closed gas circuit.

Furthermore, the device according to the invention advantageously has an extinguishing installation which is provided for each process chamber 21, 24 and is at least partially integrated in the respective suction system. In the suction system there is a thermal monitoring element which monitors the temperature in the suction system. As soon as a limit value, which can be set and adapted to the build-up material 57, is exceeded, this monitoring element emits an emergency stop signal to the control and arithmetic unit 26. The fan 109 is then shut down. At the same time, the lines 106, 114, 117, 118 are filled with shielding or inert gas and the barrier devices 176 are closed. Immediately following this, the barrier devices 176 are closed. The result of this measure is that the oxygen required for possible combustion is displaced by the shielding gas. This extinguishing installation has the advantage that following a cleaning process all the component parts can be used for the further production of molded bodies 52.

At least two process chambers 21, 24 are operated jointly by one fan 109. This fan 109 is preferably designed as a radial fan and is connected, via connecting lines 118, to the respective separation devices 107 and filters 108 of the process chambers 21, 24. This advantageous arrangement and configuration of the process chambers 21, 24, and their assignment of component parts and the incorporation of barrier devices 176, enables each process chamber 21, 24 to be autonomous and to be hermetically locked. A common beam source 16 and a common beam-diverter device 18 are also provided. The further components are provided in a number corresponding to the number of process chambers 21, 24, making it possible to produce closed material circuits both for the build-up material 57 and for the shielding or inert gas.

While a molded body 52 is being built up and produced in a process chamber 21, it is possible to carry out changeover work or to suck out build-up material 57 that has not been consolidated and/or to cool the molded body 52 in the at least one further process chamber 24, without the adjacent process chamber(s) being affected. This allows optimum utilization of the beam source 16. In addition, different molded bodies 52 with different build-up materials 57 and production parameters can be built up in each process chamber 21, 24.

The abovementioned principle is not restricted to double-chamber systems. Rather, it is also possible for three or more process chambers 21, 24 to be associated with one another. A beam-diverter device 18 may in each case be positioned with respect to the process chamber 21, 24, in order to guide a diverted beam onto the desired location within the working plane. Alternatively, it is also possible for the beam source 16 and beam-diverter device 18 to be of stationary design and for the process chambers 21, 24 to be moved relative to the beam-diverter device 18. By way of example, a turret arrangement is conceivable. In this configuration, it is also possible for both the beam-diverter device 18 and/or the radiation source 16 and the process chambers 21, 24 to be arranged displaceably relative to one another.

FIG. 7 illustrates an alternative embodiment of a build-up chamber 42 in which a removal of build-up material 57 which has not been consolidated and a cooling of the carrier 43, in particular of the at least one building platform 49, are made possible. For this purpose, at least one slot-shaped inlet opening 112 and, opposite it, at least one slot-shaped outlet opening 113 are provided in a peripheral wall 83 of the build-up chamber 42. The inlet opening 112 is supplied by a feed line 111 with ambient air which is cleaned by a filter 126.

The sucked-in volumetric flow is distributed via preferably air-guiding elements, so that, for example, a first volumetric flow of ambient air is fed to an upper section of the inlet opening 112 for removing build-up material 57 which has not been consolidated and a second volumetric flow is fed to a lower section of the inlet opening 112 in order to pass through the cooling passages 101. On the outlet side, the volumetric flows are discharged via outlet openings 113, which are assigned in each case to the inlet openings 112, and are fed, for example, to a common separation device 107 and a filter 108. The volumetric flow is controlled via a fan 109 and sucking in is made possible. It can advantageously be provided that the volumetric flows can in each case be controlled separately within the inlet opening 112, with the result that, for example, the volumetric flow for sucking out build-up material 57 which has not been consolidated can be provided to be larger than the volumetric flow for cooling the building platform 49. Throttle elements which can be controlled separately or jointly or throttle valves on the air-guiding elements can advantageously be provided in the feed line 111. As an alternative, it can be provided that the feed lines 111 are formed separately and each have a filter 126. A common outlet opening 113 is preferably provided lying opposite. The dimensioning of the cross section of the lines 111 and 114 and/or the control of the fan 109 make it possible for the volumetric flows to be controlled. Barrier devices 176 can likewise be provided for controlling the volumetric flows.

This refinement according to FIG. 7 has the advantage that, in one position of the carrier 43, the cooling and sucking-out can be undertaken simultaneously or that, in one position, the cooling and/or sucking-out can take place consecutively, with corresponding barrier devices 176 in the feed lines 111 or the inlet opening then being actuated in order to control the volumetric flows. If the carrier 43 has further cooling passages, further feed lines may also lead into the build-up chamber 42 in order to carry out a simultaneous or consecutive cooling and/or sucking-out in a cooling and suction position.

1. A process for the production of a three-dimensional molded body by successive consolidation of layers of a pulverulent build-up material, which is consolidable by means of electromagnetic radiation or particle radiation, at locations corresponding to the respective cross section of the molded body, wherein, after the molded body is finished, a carrier receiving the molded body is moved within a build-up chamber from a machining position
into a cooling position, in which at least the carrier is cooled, or
is moved into a suction position, in which the build-up material which has not been consolidated is removed from the build-up chamber, or
is moved into a cooling and suction position, in which the build-up material which has not been consolidated is removed from the build-up chamber and the carrier is cooled.

2. The process as claimed in claim 1, wherein, before or after the direct or indirect cooling of the molded body, the carrier is moved into a suction position, in which the build-up material which has not been consolidated is removed from the build-up chamber.

3. The process as claimed in claim 1, wherein a suction stream is produced in the build-up chamber at least for cooling the carrier or the molded body and for removing build-up material which has not been consolidated.

4. The process as claimed in claim 1, wherein, in a cooling position, a building platform of the carrier, which building platform receives the molded body, is passed through at least partially by the flow and is cooled.

5. The process as claimed in claim 1, wherein, in the carrier, cooling passages are assigned at least to an inlet opening arranged in the build-up chamber.

6. The process as claimed in claim 1, wherein the carrier is arranged in a cooling position in the build-up chamber and a cooling stream is produced for passing through cooling passages of the building platform and at least one further cooling stream is produced for the molded body.

7. The process as claimed in claim 1, wherein, in a suction position, a building platform of the carrier is positioned below or from below adjacent to at least one outlet opening in the build-up chamber.

8. The process as claimed in claim 1, wherein the beginning of the removal of the build-up material, which has not been consolidated, is monitored by a sensor by means of which, after a closure element is fitted onto an opening of the build-up chamber, a signal is passed on to a control and arithmetic unit.

9. The process as claimed in claim 1, wherein in order to cool or suck out build-up material which has not been consolidated a continuous volumetric flow, a volumetric flow with an increasing, pulsating or decreasing throughput volume is produced.

10. The process as claimed in claim 1, wherein residues of build-up material remaining in the build-up chamber or on the molded body after a working phase to remove build-up material which has not been consolidated are sucked out manually with a suction nozzle.

11. The process as claimed in claim 1, wherein a plurality of volumetric flows, are produced in at least two process chambers with a fan.

12. The process as claimed in claim 1, wherein a separation device and a filter are connected downstream of each process chamber and a plurality of process chambers are operated with at least one fan.

13. The process as claimed in claim 1, wherein the cooling at least of the building platform is monitored by means of at least one temperature sensor arranged in the building platform.

14. The process as claimed in claim 1, wherein the cooling speed at least of the building platform is controlled by means of a volumetric flow which is varied continuously or in a pulsed manner.

15. The process as claimed in claim 1, wherein at least the building platform is cooled down to a temperature of less than 50° C.

16. A device for the production of a three-dimensional molded body by successive consolidation of layers of a pulverulent build-up material, which is consolidated by means of electromagnetic radiation or particle radiation, at locations corresponding to the respective cross section of the molded body, in particular for carrying out the process as claimed in claim 1, with a carrier for receiving a molded body, which carrier is moveable up and down in a process chamber, at least one inlet opening and at least one outlet opening for a volumetric flow of a medium which passes through the build-up chamber being provided in at least one wall section of a build-up chamber of the process chamber, wherein at least one building platform of the carrier has cooling passages which, in a cooling position of the carrier in the process chamber, are arranged essentially congruently to the at least one inlet and outlet opening.

17. The device as claimed in claim 16, wherein the at least one inlet opening or the at least one outlet opening or the at least one inlet opening and the at least one outlet opening of the process chamber is/are in each case assigned to a barrier device.

18. The device as claimed in claim 17, wherein a respective barrier device is provided in a discharge line assigned to the outlet opening of the build-up chamber, in one or more discharge lines arranged on one or more powder traps of the process chambers.

19. The device as claimed in claim 17, wherein the barrier devices are actuated separately or in groups or jointly by a control and arithmetic unit.

20. The device as claimed in claim 16, wherein a gas, air, gas/air stream is provided at least for removing build-up material which has not been consolidated after the molded body is finished.

21. The device as claimed in claim 16, wherein the at least one inlet opening and at least one outlet opening are arranged lying opposite each other in the build-up chamber and/or the at least one inlet opening are arranged in the wall section of the build-up chamber at the same height as the at least one inlet opening or higher.

22. The device as claimed in claim 16, wherein the number of inlet openings corresponds to the number of outlet openings or in that the number of inlet openings is smaller than the number of outlet openings.

23. The device as claimed in claim 16, wherein the cooling passages of a cooling plate of the building platform have a geometry corresponding to the at least one inlet opening and the at least one outlet opening.

24. The device as claimed in claim 16, wherein at least one inlet opening and at least one outlet opening are provided at a distance below a base surface in the build-up chamber corresponding at least to the maximum overall height of a molded body to be produced.

25. The device as claimed in claim 16, wherein a throughflow rate of the volumetric flow at least for the removal of the build-up material which has not been consolidated or for cooling the carrier is controlled by an adjustable fan, or in that the throughflow rate of the volumetric flow is controlled by limiting an opening cross section of at least one inlet opening or one outlet opening.

26. The device as claimed in claim 16, wherein, for the cooling of the carrier, a filter is arranged on a feed line assigned to the inlet opening.

27-28. (canceled)

29. The process as claimed in claim 1, wherein, in the building platform cooling passages are assigned at least to an inlet opening arranged in the build-up chamber.

30. The process as claimed in claim 1, wherein the cooling of the molded body is monitored by means of at least one temperature sensor arranged in the building platform.

31. The process as claimed in claim 1, wherein the cooling speed of the molded body is controlled by means of a volumetric flow which is varied continuously or in a pulsed manner.
